(19) United States
(12) Patent Application Publication
(10) Pub. No.: US 2015/0163967 A1
(43) Pub. Date: Jun. 11, 2015

(54) MATERIAL ABSORBING LOW FREQUENCY ELECTROMAGNETIC WAVES

(71) Applicant: Hyundai Motor Company, Seoul (KR)

(72) Inventors: Inchang Chu, Seoul (KR); Jinwoo Kwak, Gyeongsan (KR)

(21) Appl. No.: 14/460,787

(22) Filed: Aug. 15, 2014

(30) Foreign Application Priority Data
Dec. 9, 2013 (KR) 10-2013-0152533

(51) Int. Cl. H05K 9/00

(52) U.S. Cl. CPC H05K 9/0083; H05K 9/00

(57) ABSTRACT

A material absorbing low frequency electromagnetic waves includes a conductive nanomaterial, and a magnetic metal nanowire or nanoparticles having greater permeability than the conductive nanomaterial. Accordingly, low frequency electromagnetic waves may be absorbed by the material in the present invention and electrical interference among various electric/electronic parts may be minimized.

### CROSS-REFERENCE TO RELATED APPLICATION

This application claims priority to and the benefit of Korean Patent Application No. 10-2013-0152533 filed in the Korean Intellectual Property Office on Dec. 9, 2013, the entire contents of which are incorporated herein by reference.

### TECHNICAL FIELD

The present invention relates to a material which may adsorb low frequency electromagnetic waves. Particularly, the present invention provides a material which may absorb low frequency electromagnetic waves generated from electric or electronic parts in a vehicle.

### BACKGROUND

Recently, electric/electronic parts have been widely used due to requirement for high integration of electric/electronic parts. Accordingly, there may be unmet need for reducing interference among the electric/electronic parts caused by electromagnetic waves, and reducing weight due to integration of electric/electronic parts.

Electric/electronic parts may also be provided in an electric vehicle or hybrid vehicle. The electric/electronic parts include a control apparatus such as an MCU (motor control unit) or a PCU (power control unit). A cable and a connector are connected to the control apparatus and the electric/electronic parts in order to supply high voltage power. However, electrical interference may be generated among the electric/electronic parts by the electromagnetic waves generated inside or outside of the various control apparatus and the electric/electronic parts, and failure of the electric/electronic parts may occur.

In the related arts, blocking both inside and outside of the electric/electronic parts, such as the MCU or PCU, has been performed using metal plates or aluminum foil, such that the electromagnetic waves generated inside or outside of various control apparatuses may leak to the outside.

As described above, when the electromagnetic waves generated inside or outside of various control apparatus is simply blocked, the intensity of the electromagnetic waves may not be reduced and a possibility of interference among the electric/electronic parts may still exist. Therefore, the intensity of the electromagnetic waves needs to be reduced.

Further, since various control apparatuses are blocked by using metal plate or aluminum foil, assembly efficiency may be reduced, weight of various parts may increase, and manufacturing cost may rise. Particularly, commercial products for absorbing high frequency electromagnetic waves over 1 GHz have been developed, but a material for absorbing low frequency electromagnetic waves has not been reported. Since the electromagnetic waves generated from a high voltage connector which is applied to a high voltage inverter are low frequency electromagnetic waves, a material for absorbing low frequency electromagnetic waves has been increasingly required.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention provides a material that may absorb low frequency band electromagnetic waves. Further, the present invention provides a material absorbing low frequency electromagnetic waves for preventing failure of various electric/electronic parts caused by low frequency electromagnetic waves. In addition, a material absorbing low frequency electromagnetic waves that may reduce weight of a part is provided.

A material absorbing low frequency electromagnetic waves according to an exemplary embodiment of the present invention may include a conductive nanomaterial, and a magnetic metal nanowire or nanoparticle which may have greater permeability than the conductive nanomaterial.

The conductive nanomaterial may be, but not limited to, one of carbon black, carbon fiber, carbon nanotubes, graphite nanoplate, or a mixture thereof.

The magnetic metal nanowire or nanoparticles may be, but not limited to, Fe, Co, Ni, FeSi, a steel alloy, a cobalt alloy, a nickel alloy, or a mixture thereof.

### BRIEF DESCRIPTION OF THE DRAWINGS

The drawings are provided for reference in describing exemplary embodiments of the present invention, and the spirit of the present invention should not be construed only by the accompanying drawings.

FIG. 1 schematically illustrates an enlarged view of an exemplary material absorbing low frequency electromagnetic waves according to an exemplary embodiment of the present invention.

FIG. 2 is an exemplary graph illustrating absorbing performance of exemplary materials absorbing low frequency electromagnetic waves which have different mixing ratio of a conductive nanomaterial and a magnetic metal nanowire in an exemplary embodiment of the present invention.

FIG. 3 is an exemplary graph illustrating absorbing performance of exemplary materials absorbing low frequency electromagnetic waves which have different permeability in an exemplary embodiment of the present invention.

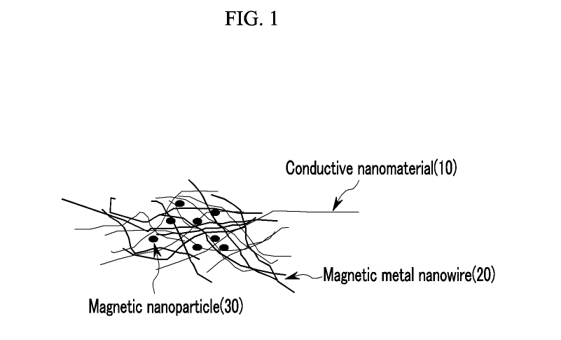

Reference numerals set forth in the FIG. 1 include reference to the following elements as further discussed below:

10: conductive nanomaterial

20: magnetic metal nanowire

30: magnetic metal nanoparticle

### DETAILED DESCRIPTION OF THE EMBODIMENTS

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In describing the present invention, parts that are not related to the description will be omitted. Like reference numerals generally designate like elements throughout the specification.

In addition, the size and thickness of each configuration shown in the drawings are arbitrarily shown for better understanding and ease of description, but the present invention is not limited thereto. In the drawings, the thickness of layers, films, panels, regions, etc., are exaggerated for clarity.

A material absorbing low frequency electromagnetic waves according to an exemplary embodiment of the present invention will now be described with reference to drawings.

FIG. 1 schematically illustrates an enlarged view of an exemplary material for absorbing low frequency electromagnetic waves according to an exemplary embodiment of the present invention.

As shown in FIG. 1, a material for absorbing low frequency electromagnetic waves according to an exemplary embodiment of the present invention may include a conductive nanomaterial 10, and a metal nanowire 20 or nanoparticle 30. Permeability of the conductive nanowire 20 or nanoparticle 30 may be greater than the permeability of the conductive nanomaterial 10.

The conductive nanomaterial 10 may be, but not limited to, any one of carbon black (CB), carbon fiber (CF), carbon nanotubes (CNT), graphite nanoplate (GNP), or a mixture thereof. The magnetic metal nanowire 20 or nanoparticle 30 may be, but not limited to, any one of iron (Fe), nickel (Ni), ferro-silicon (FeSi), a steel alloy, a cobalt alloy, a nickel alloy, or a mixture thereof.

Since the conductive nanomaterial 10 may partially conduct heat or light, the conductive nanomaterial 10 may block or reflect a certain amount of electromagnetic waves. Simultaneously, the conductive nanomaterial 10 may absorb electromagnetic waves and convert them into heat. In particular, the characteristic of absorbing the electromagnetic waves may be improved by mixing the conductive nanomaterial 10 with a magnetic metal nanowire 20 or nanoparticle 30.

An article, for the electric/electronic parts using the material absorbing low frequency electromagnetic waves according to an exemplary embodiment of the present invention may be manufactured by mixing a polymer compound, the conductive nanomaterial 10, and the magnetic metal nanowire 20 or nanoparticle 30. Herein, the article may be, but not limited to, a housing, a cable, or a connector of electric/electronic parts in a vehicle; and the polymer compound may be, but not limited to, polypropylene (PP) or polyethylene (PE).

As described above, when the article, such as the housing, the cable, or the connector, is manufactured by mixing the polymer compound, the conductive nanomaterial 10, and the magnetic metal nanowire 20 or nanoparticle 30, strength, heat resistance, flame retardancy, electrical insulation, and a function of absorbing the electromagnetic waves thereof may be improved.

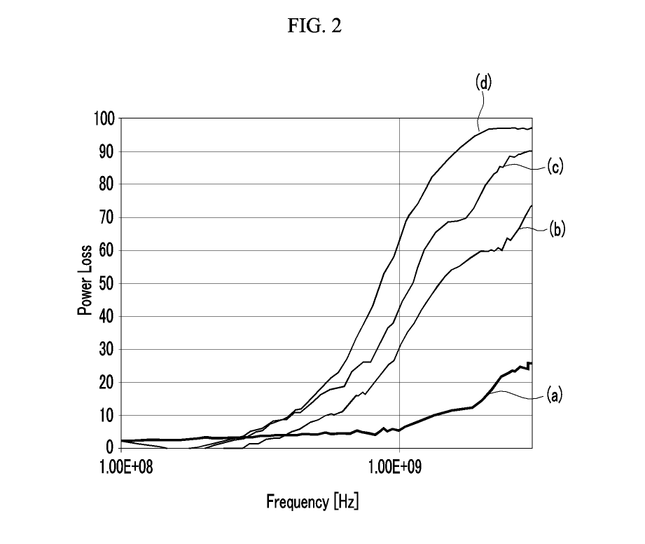

FIG. 2 is an exemplary graph illustrating absorbing performance of exemplary materials absorbing low frequency electromagnetic waves which have different mixing ratios of a conductive nanomaterial and a magnetic metal nanowire. In FIG. 2, according to an exemplary embodiment, the polypropylene (PP) as of the polymer compound, the conductive nanomaterial 10, and the magnetic metal nanomaterial are mixed at various mixing ratio. Further, in FIG. 2, the horizontal axis shows a frequency of the electromagnetic waves in a log scale, and the vertical axis shows electrical power loss of the electromagnetic wave, i.e. absorbing performance of the electromagnetic waves of the materials. In an exemplary embodiment of the present invention, the electrical power loss may be measured as a value of an output electrical power ratio to an input electric power. Thus, the electrical power loss may be interpreted proportionally to the absorbing performance of the electromagnetic waves.

Further, in FIG. 2, a line (a) may indicate a measured result of the electrical power loss when using an exemplary material including the polypropylene and the graphite nanoplate (GNP) in an amount of about 10 wt %; and the material of line (a) may partially absorb high frequency electromagnetic waves. A line (b) in FIG. 2 may indicate a measured result of the electrical power loss when using an exemplary mixed material including the polypropylene and the graphite nanoplate (GNP) in an amount of about 40 wt %; the material of line (b) may have substantially high absorbing performance of electromagnetic waves compared to the material of line (a) including the graphite nanoplate (GNP) in an amount of about 10 wt %. A line(c) in FIG. 2 may indicate a measured result of the electrical power loss when using an exemplary mixed material including the polypropylene and the carbon nanotubes (CNT) in an amount of about 10 wt %; and the material of line (c) may have greater absorbing performance of electromagnetic waves than the material of line (b) including the graphite nanoplate (GNP) in an amount of about 40 wt %. A line (d) in FIG. 2 may indicate a measured result of the electrical power loss when using an exemplary mixed material including the polypropylene and sendust in an amount of about 10 wt %; and the material of line (d) may have greater absorbing performance of electromagnetic waves than the mixed material including the graphite nanoplate (GNP) or carbon nanotubes (CNT), and absorb lower frequency electromagnetic waves. As used herein, the sendust is a high permeability alloy with a composition of aluminum, silicon, and steel.

As described above, when the mixed material including the polypropylene as of a polymer compound, the conductive nanomaterial 10 such as the graphite nanoplate (GNP) or carbon nanotubes (CNT), and the magnetic metal nanoparticles 30 such as the sendust is used, the absorbing performance may be improved. Particularly, the absorbing performance of low frequency electromagnetic waves may be improved.

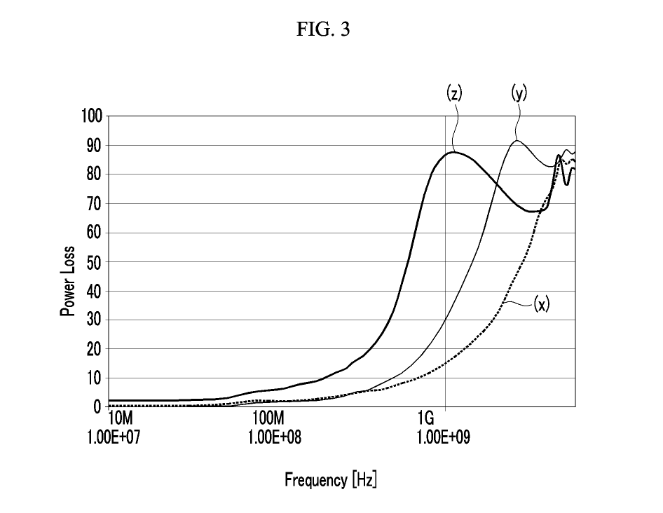

FIG. 3 is an exemplary graph illustrating absorbing performance of exemplary materials absorbing low frequency electromagnetic waves which have different permeability according to an exemplary embodiment of the present invention. FIG. 3 shows results of absorbing performance of the electromagnetic waves according to materials that may be manufactured by mixing the polypropylene and sendust at various composition ratios.

In FIG. 3, permeability of line (x) is about 21; permeability of line (y) is about 89; and permeability of line (z) is about 128. As results, when permeability of the material is lower, the material absorbs higher frequency band electromagnetic waves.

Accordingly, when the conductive nanomaterial 10 is mixed with the magnetic metal nanoparticles 30 with different permeabilities, a material that absorbs a desired band frequency of electromagnetic waves may be obtained.

As described above, according to an exemplary embodiment of the present invention, a housing of electric/electronic parts such as an media control unit (MCU) or power control unit (PCU), or a cable or connector supplying high voltage power to the MCU or PCU, may be manufactured, and thus low frequency electromagnetic waves generated from the MCU or PCU, or low frequency electromagnetic waves generated when supplying high voltage power, may be absorbed and electrical interference may be avoided.

Further, according to an exemplary embodiment of the present invention, when the housing is manufactured by using the material absorbing low frequency electromagnetic waves, the housing or the connector or the cable may be reduced in weight, since a metal material may not be used therein for blocking the electromagnetic waves, and further an anti-corrosion function of each part may be improved.

In various exemplary embodiments, the magnetic metal nanowire 20 or nanoparticles 30 may be added into pores of the conductive nanomaterial 10. Accordingly, porosity of the material may increase and a filling rate of the material may increase. Therefore, the material absorbs low frequency band electromagnetic waves and volume of each part may be reduced.

Further, according to various exemplary embodiments of the present invention, since a material absorbing low frequency electromagnetic waves may be prepared by mixing a conductive nanomaterial and a magnetic metal nanowire or nanoparticles having greater permeability than the conductive nanomaterial, the low frequency electromagnetic waves may be absorbed and electrical interference among various electric/electronic parts may be minimized.

Further, since a heavy material such as a metal plate or aluminum foil is not used to block electromagnetic waves, parts for absorbing and blocking electromagnetic waves may be reduced in weight.

While this invention has been described in connection with what is presently considered to be exemplary embodiments, it is to be understood that the invention is not limited to the disclosed embodiments, but, on the contrary, is intended to cover various modifications and equivalent arrangements included within the spirit and scope of the appended claims.

What is claimed is:

1. A material absorbing low frequency electromagnetic waves, comprising:
a conductive nanomaterial; and
a magnetic metal nanowire or nanoparticles having high permeability compared to the conductive nanomaterial.

2. The material absorbing low frequency electromagnetic waves of claim 1,
wherein the conductive nanomaterial is selected from the group consisting of carbon black, carbon fiber, carbon nanotubes, graphite nanoplate, and a mixture thereof.

3. The material absorbing low frequency electromagnetic waves of claim 1,
wherein the magnetic metal nanowire or nanoparticle is selected from the group consisting of Fe, Co, Ni, FeSi, a steel alloy, a cobalt alloy, a nickel alloy, and a mixture thereof.

4. An article manufactured from the material absorbing low frequency electromagnetic waves of claim 1.

5. The article of claim 4, wherein the article is a housing, a cable, or a connector of electric/electronic parts in a vehicle
